(19) United States
(12) Patent Application Publication
(10) Pub. No.: US 2008/0311731 A1
(43) Pub. Date: Dec. 18, 2008

(54) LOW PRESSURE CHEMICAL VAPOR DEPOSITION OF POLYSILICON ON A WAFER

(75) Inventor: Tae Gil KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/139,341

(22) Filed: Jun. 13, 2008

(30) Foreign Application Priority Data
Jun. 14, 2007 (KR) 10-2007-0058422

(51) Int. Cl. H01L 21/205; C23C 16/00

(52) U.S. Cl. 438/488; 118/715; 257/E21.102

(57) ABSTRACT

Low pressure chemical vapor deposition (LPCVD) of polysilicon on a wafer in a manner that reduces the generation of particles during the deposition process. In one example embodiment, a method of LPCVD of polysilicon on a wafer positioned in a process tube includes various steps. First, introducing a particle inhibitor is introduced into the process tube. Next, a silicon source gas is introduced into the process tube. Finally, a doping gas is introduced into the process tube, resulting in the formation of a polysilicon film of a uniform thickness on the wafer.

### CROSS-REFERENCE TO A RELATED APPLICATION

This application claims the benefit of Korean Patent Application No. 10-2007-0058422, filed on Jun. 14, 2007, which is hereby incorporated by reference as if fully set forth herein.

### BACKGROUND

1. Field of the Invention

The present invention relates to depositing polysilicon on a wafer during the fabrication of semiconductor devices and, more particularly, to low pressure chemical vapor deposition (LPCVD) of polysilicon on a wafer in a manner that reduces the generation of particles during the deposition process.

2. Description of the Related Art

Typically, LPCVD is a method of depositing a desired film on a top surface of a wafer by supplying gas to a deposition furnace while a low pressure state is maintained within the furnace. During LPCVD, a thin film is typically deposited using chemical vapor deposition (CVD) at a pressure in the range of 0.1 to 50 torr, unlike in conventional atmospheric pressure CVD (APCVD) where a thin film is deposited at atmospheric pressure. During LPCVD, CVD is performed at a low reaction gas pressure so that the thin film is deposited uniformly on the surface of a wafer. Accordingly, LPCVD has been used extensively in depositing polysilicon films, nitride films, and oxide films.

When LPCVD is employed to deposit polysilicon on a wafer, gas at a low pressure is first supplied into a deposition furnace through a gas supply passage by opening a supply valve within the furnace. Polysilicon having a small grain size is then deposited on the wafer at a relatively slow deposition rate and at a relatively low temperature. A surface of the polysilicon is then annealed in a nitrogen gas ambient at a relatively high temperature. However, if particles are generated during the deposition of polysilicon, the polysilicon is not easily recrystallized during annealing and the particles remain on the surface of the wafer.

FIG. 1 discloses the generation of particles during conventional LPCVD of polysilicon on a wafer 10. As disclosed in FIG. 1, when polysilicon is deposited on the wafer 10 during conventional LPCVD, a doping gas PH₃ and a silicon source gas SiH₄ are introduced into a process tube and are formed into polysilicon having a relatively large grain size due to an abnormal reaction. Upon deposition onto the surface of the wafer 10, this polysilicon having a relatively large grain size is referred to as “particles.” Particles deposited onto the surface of the wafer 10 degrade the reliability of the semiconductor devices formed from the wafer 10.

### SUMMARY OF EXAMPLE EMBODIMENTS

In general, example embodiments of the invention relate to low pressure chemical vapor deposition (LPCVD) of polysilicon on a wafer in a manner that reduces the generation of particles during the deposition process.

In one example embodiment, a method of LPCVD of polysilicon on a wafer positioned in a process tube includes various steps. First, introducing a particle inhibitor is introduced into the process tube. Next, a silicon source gas is introduced into the process tube. Finally, a doping gas is introduced into the process tube, resulting in the formation of a polysilicon film of a uniform thickness on the wafer.

In another example embodiment, an LPCVD apparatus capable of polysilicon deposition includes a process tube, a gas supplier, and a vacuum pump. The process tube is configured to deposit polysilicon on a wafer surface using LPCVD in a vacuum state. The gas supplier is configured to sequentially introduce an inert gas, a silicon source gas, and a doping gas into the process tube in order to deposit polysilicon on the wafer. The vacuum pump is configured to form a vacuum state within the process tube.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of example embodiments of the invention and are incorporated in and constitute a part of this application, illustrate example embodiments of the invention. In the drawings:

FIG. 1 discloses the generation of particles during conventional LPCVD of polysilicon on a wafer;

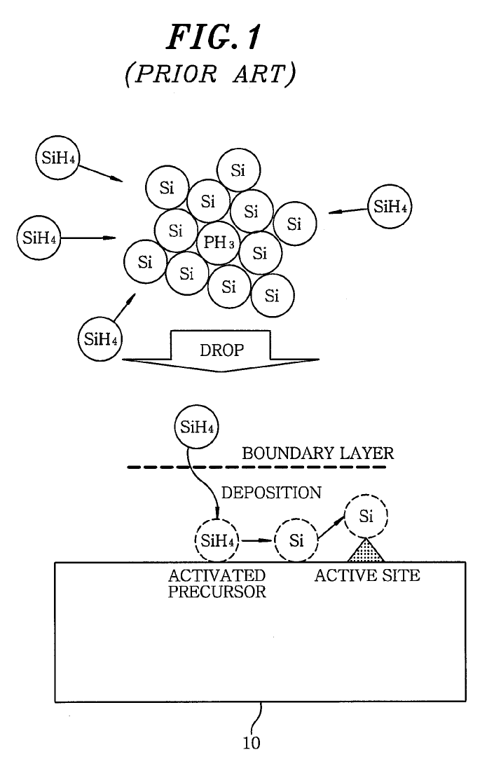

FIG. 2 discloses an example LPCVD apparatus capable of polysilicon deposition; and

FIG. 3 discloses LPCVD of polysilicon in a manner that reduces the generation of particles during the deposition process.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

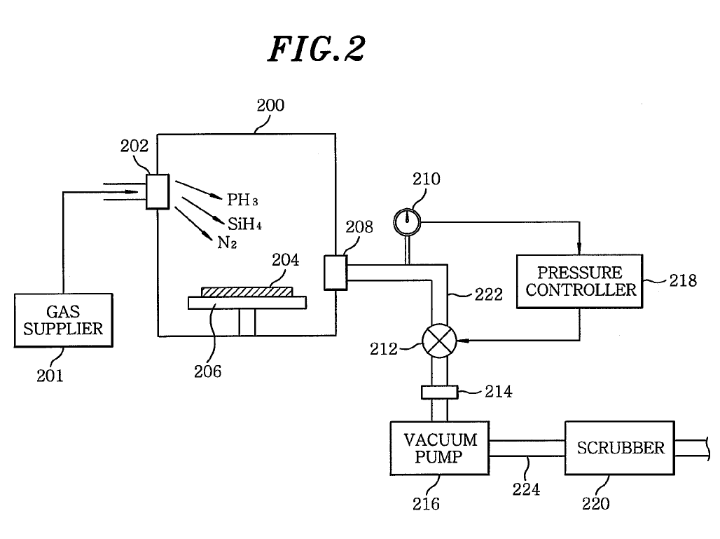

FIG. 2 discloses an example LPCVD apparatus capable of polysilicon deposition. In particular, the example LPCVD apparatus can be used to deposit polysilicon on a wafer in a manner that reduces the generation of particles during the deposition process. The example LPCVD apparatus generally includes a process tube 200, a gas supplier 201, a vacuum pump 216, a pressure controller 218, and a scrubber 220.

With continuing reference to FIG. 2, additional details regarding the structure and operation of the example LPCVD apparatus are disclosed. The gas supplier 201 is configured to supply process gases and other gas(es) to the process tube 200 for use in LPCVD. The vacuum pump 216 is coupled to the process tube 200 through a pumping line 222. The pumping line 222 includes a main valve 212. The pressure controller 218 is configured to monitor the pressure within the process tube 200 and within the pumping line 222 and control the opening/closing of the main valve 212. The scrubber 220 is coupled to the vacuum pump 216 through an exhaust line 224. The process tube 200 includes a wafer support 206 positioned within the process tube 200 upon which a wafer 204 may be supported. The process tube 200 also includes a gas inlet port 202 and a gas outlet port 208. Gas(es) from the gas supplier 201 may be introduced through the gas inlet port 202, and gas(es) may be discharged into the pumping line 222 through the outlet port 208.

During the operation of the example LPCVD apparatus, the vacuum pump 216 reduces an internal pressure of the process tube 200 through a pumping operation so as to form a predetermined vacuum atmosphere within the process tube 200 that is suitable for polysilicon deposition. Then, a polysilicon deposition process is performed on a surface of the wafer 204. This polysilicon deposition is accomplished as the gas supplier 201 sequentially introduces an inert gas, a silicon source gas, and a doping gas through the inlet port 202 into the process tube 200.

Afterward, the gases are discharged into the pumping line 222 through the outlet port 208. A pressure gauge 210 measures the internal pressure of the pumping line 222 and transmits measured pressure data to the pressure controller 218. The pressure controller 218 receives the pressure data from the pressure gauge 210 and controls the operation of the main valve 212 based on the data, thereby automatically controlling the flow rate of the discharge gas passing through the pumping line 222. A cold trap 214 filters any powder carried by the discharge gas in order to prevent malfunction of the vacuum pump 216 due to the adhesion of powder on the inside of the vacuum pump 216. The scrubber 220 then purifies harmful elements from the discharge gases before releasing the discharge gases into the environment.

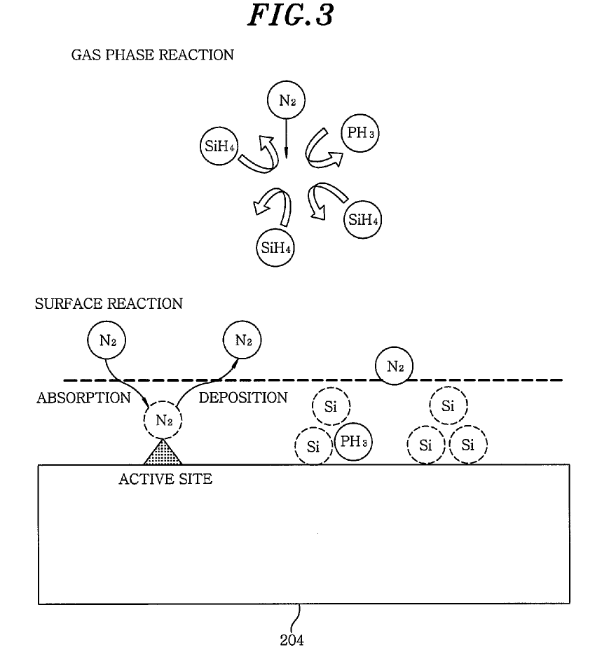

With continuing reference to FIG. 2, and with reference now also to FIG. 3, aspects of an example method of LPCVD of polysilicon on a wafer are disclosed. Prior to the deposition of polysilicon, the wafer 204 is placed on the wafer support 206 within the process tube 200 of the LPCVD apparatus disclosed in FIG. 2, the main valve 212 of the pumping line 222 is opened, and the vacuum pump 216 is actuated. These steps result in the internal pressure of the process tube 200 being reduced to form a predetermined vacuum atmosphere suitable for polysilicon deposition. The pressure gauge 210 measures the predetermined vacuum atmosphere and transmits measured pressure data to the pressure controller 218. The pressure controller 218 then controls the opening and closing of the main valve 212 so that the inside of the process tube 200 can maintain a vacuum state.

After a vacuum state suitable for polysilicon deposition has been created within the process tube 200, a particle inhibitor is first introduced into the process tube 200 through the inlet port 202 as an inhibitor for reducing particles on the wafer 204. The particle inhibitor may be, for example, an inert gas, such as N₂ or He gas.

Thereafter, a doping gas, such as PH₃, and a silicon source gas, such as SiH₄, are sequentially introduced into the process tube 200 through the gas inlet port 202. The doping gas and the silicon source gas then react to each other so that a polysilicon thin film is deposited on a surface of the wafer 204.

The particle inhibitor, which is present in the process tube 200 before the doping gas and the silicon source gas are introduced into the process tube 200, infiltrates between the doping gas and the silicon source gas thus prohibiting a gas phase reaction, as disclosed in FIG. 3. Accordingly, the silicon source gas and the doping gas are prevented from forming polysilicon having a relatively large grain size due to an abnormal reaction. Consequently, the particle inhibitor causes a reduction in the generation of particles during LPCVD of polysilicon.

As described above, the example method of LPCVD of polysilicon introduces a particle inhibitor into the process tube before the silicon source gas and the doping gas are introduced into the process tube, thus preventing a gas phase reaction between the silicon source gas and the doping gas. The example method results in a reduction in the generation of particles of a relatively large grain size during the polysilicon deposition process.

Although example embodiments of the present invention have been shown and described, changes might be made in these example embodiments. The scope of the invention is therefore defined in the following claims and their equivalents.

What is claimed is:

1. A method of low pressure chemical vapor deposition (LPCVD) of polysilicon on a wafer positioned in a process tube, the method comprising the steps of:
introducing a particle inhibitor into the process tube;
introducing a silicon source gas into the process tube;
introducing a doping gas into the process tube, resulting in the formation of a polysilicon film of a uniform thickness on the wafer.

2. The method of claim 1, wherein the particle inhibitor comprises an inert gas.

3. The method of claim 2, wherein the inert gas comprises N₂.

4. The method of claim 2, wherein the inert gas comprises He.

5. The method of claim 1, wherein the silicon source gas comprises SiH₄.

6. The method of claim 1, wherein the doping gas comprises PH₃.

7. An LPCVD apparatus capable of polysilicon deposition, the LPCVD apparatus comprising:
a process tube configured to deposit polysilicon on a wafer surface using LPCVD in a vacuum state;
a gas supplier configured to sequentially introduce a particle inhibitor, a silicon source gas, and a doping gas into the process tube in order to deposit polysilicon on the wafer; and
a vacuum pump configured to form a vacuum state within the process tube.

8. The LPCVD apparatus of claim 7, wherein the particle inhibitor functions to prohibit a gas phase reaction between the silicon source gas and the doping gas.

9. The LPCVD apparatus of claim 7, wherein the particle inhibitor comprises an inert gas.

10. The LPCVD apparatus of claim 9, wherein the inert gas comprises N₂.

11. The LPCVD apparatus of claim 9, wherein the inert gas comprises He.

12. The LPCVD apparatus of claim 7, wherein the silicon source gas comprises SiH₄.

13. The LPCVD apparatus of claim 7, wherein the doping gas comprises PH₃.
